(19) United States
(12) Patent Application Publication
(10) Pub. No.: US 2019/0198364 A1
(43) Pub. Date: Jun. 27, 2019

(54) EXCIMER LASER ANNEALING APPARATUS

(71) Applicant: Wuhan China Star Optoelectronics Semiconductor Display Technology Co., Ltd., Wuhan (CN)

(72) Inventors: Weibin ZHANG, Shenzhen (CN); Rui XIE, Shenzhen (CN); Fanlin ZENG, Shenzhen (CN)

(21) Appl. No.: 15/996,396

(22) Filed: Jun. 1, 2018

Related U.S. Application Data
(63) Continuation of application No. PCT/CN2018/074344, filed on Jan. 26, 2018.

(30) Foreign Application Priority Data
Dec. 27, 2017 (CN) 201711449637.9

(51) Int. Cl. H01L 21/67; B23K 26/00; B23K 26/06; B23K 26/10; B23K 26/354; C03B 25/02; H01L 21/02

(52) U.S. Cl. CPC H01L 21/67115; B23K 26/0006; B23K 26/0648; B23K 26/10; B23K 26/0643; B23K 2203/56; C03B 25/02; H01L 21/67248; H01L 21/02592; H01L 21/02532; H01L 21/0268; B23K 26/354

(57) ABSTRACT

The present disclosure provides an excimer laser annealing apparatus for laser annealing a substrate, including a beam current consumer, a focusing lens, and a laser. The beam current consumer is disposed between the substrate and the laser, the focusing lens is disposed between the beam current consumer and the laser and is located on the optical path of the laser beam of the laser directed onto the substrate, the focus of the focusing lens is on the optical path of the laser beam of the laser directed onto the substrate and on the substrate, the beam current consumer is provided with a transmission cavity and a reflection cavity connecting with the transmission cavity, the reflection cavity includes a surface provided with a reflection film, the laser beam generated by the laser is focused by the focusing lens and then emitted to the substrate through the transmission cavity.

### RELATED APPLICATIONS

This application is a continuation application of PCT Patent Application No. PCT/CN2018/074344, filed Jan. 26, 2018, which claims the priority benefit of Chinese Patent Application No. CN 201711449637.9, filed Dec. 27, 2017, which is herein incorporated by reference in its entirety.

### FIELD OF THE DISCLOSURE

The present disclosure relates to a display technology field, and more particularly to an excimer laser annealing apparatus.

### BACKGROUND OF THE DISCLOSURE

Excimer laser annealing (ELA) technology has been widely used in the semiconductor industry. In the conventional ELA apparatus manufacturing process, the laser beam is generally focused by the optical system and then irradiated onto the silicon substrate at an oblique angle. A part of the laser beam is absorbed by silicon and a part of the laser beam is reflected by the silicon film to the beam current consumer. The beam current consumer almost absorbed all the energy of the reflected light, and the light energy into heat, resulting in the utilization of energy is not high and will lead to the temperature rise of the beam current consumer, thus affecting the life of the excimer laser annealing apparatus.

### SUMMARY OF THE DISCLOSURE

The purpose of the present disclosure is to provide an excimer laser annealing, which solves the technical problem of increasing the temperature of the beam current consumer.

The present disclosure provides an excimer laser annealing apparatus for laser annealing a substrate, including a beam current consumer, a focusing lens, and a laser. The beam current consumer is disposed between the substrate and the laser, the focusing lens is disposed between the beam current consumer and the laser and is located on the optical path of the laser beam of the laser directed onto the substrate, the focus of the focusing lens is on the optical path of the laser beam of the laser directed onto the substrate and on the substrate, the beam current consumer is provided with a transmission cavity running through the beam current consumer and a reflection cavity connecting with the transmission cavity, the reflection cavity includes a surface provided with a reflection film, the surface faces the substrate, the laser beam generated by the laser is focused by the focusing lens and then emitted to the substrate through the transmission cavity, the substrate reflects the focused laser beam onto the reflective film and is reflected back to the substrate via the reflective film.

The surface of the reflecting cavity includes an arc-shaped surface, the reflective film is an arc-shaped film, the reflective film is attached to the arc-shaped surface, a center of the arc-shaped surface is located on the optical path of the laser beam of the laser directed onto the substrate and is located on the substrate.

The reflective film includes a first thin film layer and a second thin film layer alternately arranged in layers, and the first thin film layer is disposed on an outermost layer and an innermost layer of the reflective film, the first film layer has a first refractive index, the second film layer has a second refractive index, and the first refractive index is greater than the second refractive index.

The first thin film layer and the second thin film layer have a same thickness.

The thicknesses of the first thin film layer and the second thin film layer are both an integral multiple of a quarter of a wavelength of the laser.

The first thin film layer includes at least one of a silicon nitride film layer, a titanium dioxide film layer, a tantalum pentoxide thin film layer, a zirconium oxide thin film layer, a lanthanum titanate thin film layer, a hafnium oxide thin film layer, and a zinc selenide thin film layer.

The second thin film layer includes at least one of a magnesium fluoride thin film layer, a silicon oxide thin film layer, an aluminum oxide thin film layer, and a titanium nitride thin film layer.

The excimer laser annealing apparatus includes an energy meter for detecting the energy of the laser reflected by the reflection film.

The excimer laser annealing apparatus includes a supporter that supports the substrate.

The substrate is an amorphous silicon substrate.

To sum up, the reflective film of the present disclosure reflects the reflected light beam reaching the reflective film, thereby reducing the absorption of the laser light by the beam current consumer and solving the technical problem that the temperature of the current consumer increases, so that the cooling device for the beam current consumer is omitted; meanwhile, the laser beam reflected by the reflective film is irradiated onto the substrate again, thereby improving the utilization rate of the laser beam.

### BRIEF DESCRIPTION OF THE DRAWINGS

To describe the technical solutions in the embodiments of the present disclosure or in the prior art more clearly, the following briefly introduces the accompanying drawings required for describing the embodiments or the prior art. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of an excimer laser annealing apparatus according to an embodiment of the present disclosure.

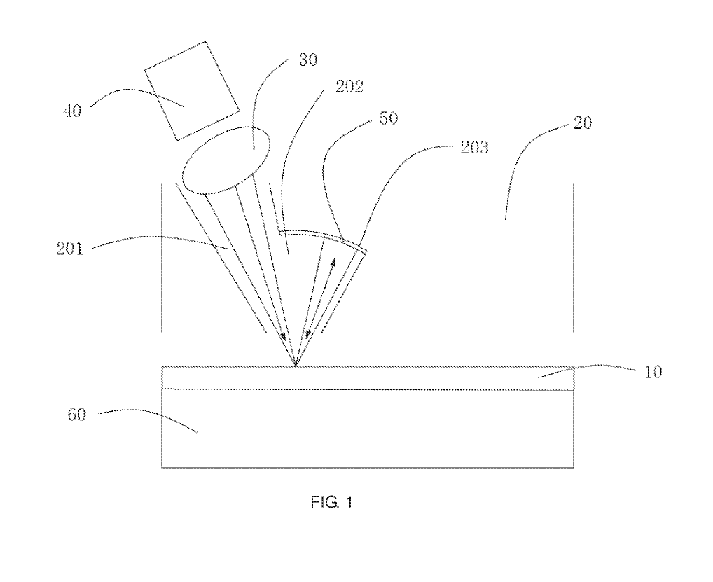

FIG. 2 is a schematic structural diagram of the reflective film in FIG. 1.

### DETAILED DESCRIPTION OF PREFERRED EMBODIMENTS

The technical solutions in the embodiments of the present disclosure will be described clearly and completely hereinafter with reference to the accompanying drawings in the embodiments of the present disclosure. Apparently, the described embodiments are merely some but not all embodiments of the present disclosure. All other embodiments obtained by persons of ordinary skill in the art based on the embodiments of the present disclosure without creative efforts shall fall within the protection scope of the present disclosure.

The present disclosure provides an excimer laser annealing apparatus for laser annealing a substrate 10, including a beam current consumer 20, a focusing lens 30, and a laser 40. The beam current consumer 20 is between the substrate 10 and the laser 40, the focusing lens 30 is disposed between the beam current consumer 20 and the laser 40 and located on the optical path of the laser beam of the laser 40 directed onto the substrate 10. The focus of the focusing lens 30 is on the optical path of the laser beam of the laser 40 directed onto the substrate 10 and on the substrate 10. The beam current consumer 20 is provided with a transmission cavity 201 penetrating the beam current consumer 20 and a reflection cavity 202 connecting with the transmission cavity 201. The reflective cavity 202 includes a surface 203 provided with a reflective film 50, the surface 203 faces the substrate 10, the laser beam generated by the laser 40 is focused by the focusing lens 30 and then emitted to the substrate 10 through the transmission cavity 201, the substrate 10 reflects the focused laser beam onto the reflective film 50 and then reflects the laser beam back onto the substrate 10 through the reflective film 50. The reflective film 50 of the present disclosure reflects the reflected laser beam reaching the reflective film 50 to reduce the absorption of the laser beam by the beam current consumer 20 and solve the technical problem that the temperature of the beam current consumer 20 rises. And further the cooling device for the beam current consumer 20 is omitted. At the same time, the laser beam reflected by the reflection film 50 irradiates the substrate 10 again, which improves the utilization rate of the laser beam.

In this embodiment, the substrate 10 is an amorphous silicon substrate, and after laser annealing by the excimer laser annealing device, the substrate 10 is crystallized into a polycrystalline silicon substrate. The substrate 10 is supported by a supporter 60. The focusing lens 30 is a convex lens. The focused laser beam irradiates the substrate 10 in a direction that is 7 degrees from the perpendicular of the substrate 10. The transmission cavity 201 is a cavity penetrating the beam current consumer 20. The reflection cavity 202 is a fan-shaped cavity. The transmission cavity 201 is a chamber through which the laser beam generated by the laser 40 passes in the beam current consumer 20. The reflection cavity 202 is a cavity in the beam current consumer 20 through which the laser beam reflected by the substrate 10 passes, and the reflection cavity 202 is a cavity in the beam current consumer 20 through which the laser beam reflected by the reflection film 50 passes.

In this embodiment, the surface 203 of the reflection cavity 202 is an arc-shaped surface, the reflection film 50 is an arc-shaped film, the reflection film 50 is attached to the arc-shaped surface, the center of the arc-shaped surface reaches the position of the substrate 10 after the laser beam is focused. Specifically, the arc-shaped reflective film 50 is attached to the arc-shaped surface of the beam current consumer 20, and the center of the arc-shaped curved surface is located on the optical path of the substrate 10 when the laser beam of the laser 40 is located on the substrate 10, that is, the center of the arc-shaped reflective film 50 is also located on the optical path of the laser beam of the laser 40 directed onto the substrate 10 and on the substrate 10. The arc-shaped reflection film 50 realizes that the laser beam reflected to the reflection film 50 is reflected to the substrate 10 along the reverse direction that the laser beam reaches the reflection film 50, and the laser beam reflected by the reflection film 50 can irradiate the center position of the reflection film 50, the laser beam irradiating the substrate 10 and emitted by the laser 40 irradiates the same position of the substrate 10 to improve the utilization rate of the laser beam. However, since the energy of the laser beam is attenuated during the reflection of the laser beam, when the laser beam reflected by the reflection film 50 is irradiated to the substrate 10, the energy of the laser beam is already small. Furthermore, when the laser beam is further reflected by the substrate 10 and irradiated to the laser 40, the energy of the laser beam will be smaller and the laser 40 will not be affected.

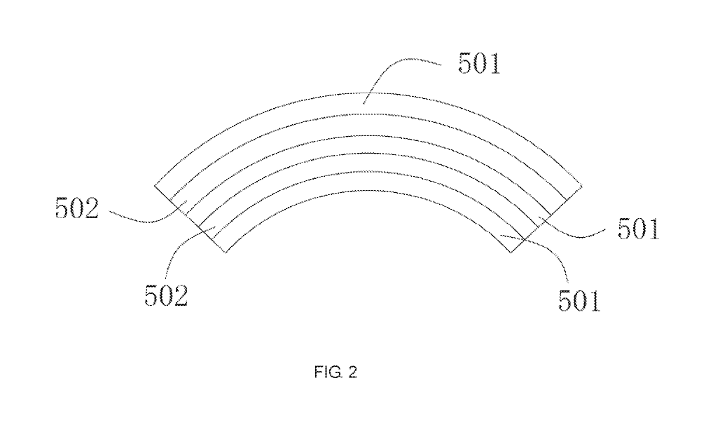

Please refer to FIG. 2, the reflective film 50 includes a first film layer 501 and a second film layer 502 that are alternately stacked, and the first film layer 501 is disposed on the outermost layer and the innermost layer of the reflective film 50. The first thin film layer 501 has a first refractive index, the second thin film layer 502 has a second refractive index, and the first refractive index is greater than the second refractive index. Specifically, the reflective film 50 includes a first film layer 501 and a second film layer 502. The first film layer 501 and the second film layer 502 are alternately stacked, and the innermost layer and the outermost layer of the reflective film 50 are both the first film layer 501. That is, the laser beam reflected by the substrate 10 first comes into contact with the first thin film layer 501 having the first refractive index, since the refractive index of the first thin film layer 501 is greater than the refractive index of the second thin film layer 502, part of the laser light reaching the first thin film layer 501 is reflected and partially refracted, the laser beam entering the second thin film layer 502 is further reflected and refracted until reaching the first thin film layer 501 in contact with the arcuate curved surface of the reflective cavity 202.

In this embodiment, the thickness of the first film layer 501 and the thickness of the second film layer 502 are equal. The thicknesses of the first thin film layer 501 and the second thin film layer 502 are both integral multiples of a quarter of the laser wavelength. Specifically, the first thin film layer 501 and the second thin film layer 502 have the same thickness and a positive integral multiple of a quarter of the laser wavelength. Since under this condition, the reflected light vectors and the vibration directions of the respective laminated layers are the same, the amplitude of the synthesized reflected light increases as the number of thin film layers increases and the energy increases, the energy of the laser beam reflected by the reflective film 50 and irradiated onto the substrate 10 is still high, thereby further improving the utilization rate of the laser beam. Furthermore, as the number of thin film layers increases, the refracted light entering the beam current consumer 20 after refraction is reduced, the influence on the beam current consumer 20 is small, and the cooling device of the beam current consumer 20 is omitted.

In this embodiment, the first thin film layer 501 includes a silicon nitride film layer, a titanium dioxide film layer, a tantalum pentoxide film layer, a zirconium oxide film layer, a lanthanum titanate film layer, a hafnium oxide film layer, and a zinc selenide film layer. The second thin film layer 502 includes a magnesium fluoride thin film layer, a silicon oxide thin film layer, an aluminum oxide thin film layer and a titanium nitride thin film layer. Therefore, during the staggered stacking of the first thin film layer 501 and the second thin film layer 502, the first thin film layer 501 may be one of a silicon nitride film layer, a titanium dioxide film layer, a tantalum pentoxide thin film layer, a zirconium oxide thin film layer, a lanthanum titanate thin film layer, a hafnium oxide thin film layer and a zinc selenide film layer, or a combination of any several of them. The second thin film layer 502 may be one of a magnesium fluoride thin film layer, a silicon oxide thin film layer, an aluminum oxide thin film layer and a titanium nitride thin film layer, or a combination of any several of them.

The excimer laser annealing apparatus includes an energy meter (not shown in the figure) for detecting the energy of the laser light reflected. Specifically, the energy meter is disposed in the beam current consumer 20 at a position close to the reflection film 50. The energy meter is used for detecting the energy of the laser light reflected by the reflective film 50 and further determining the number of layers of the first film layer 501 and the second film layer 502 in the reflective film 50.

The above disclosure is only the preferred embodiments of the present disclosure, and certainly can not be used to limit the scope of the present disclosure. Persons of ordinary skill in the art may understand that all or part of the procedures for implementing the foregoing embodiments and equivalent changes made according to the claims of the present disclosure still fall within the scope of the present disclosure.

What is claimed is:

1. An excimer laser annealing apparatus for laser annealing a substrate, comprising a beam current consumer, a focusing lens, and a laser, wherein the beam current consumer is disposed between the substrate and the laser, the focusing lens is disposed between the beam current consumer and the laser and is located on an optical path of the laser beam of the laser directed onto the substrate, a focus of the focusing lens is on the optical path of the laser beam of the laser directed onto the substrate and on the substrate, the beam current consumer is provided with a transmission cavity running through the beam current consumer and a reflection cavity connecting with the transmission cavity, the reflection cavity comprises a surface provided with a reflection film, the surface faces the substrate, the laser beam generated by the laser is focused by the focusing lens and then emitted to the substrate through the transmission cavity, the substrate reflects the focused laser beam onto the reflective film and is reflected back to the substrate via the reflective film.

2. The excimer laser annealing apparatus according to claim 1, wherein the surface of the reflecting cavity comprises an arc-shaped surface, the reflective film is an arc-shaped film, the reflective film is attached to the arc-shaped surface, a center of the arc-shaped surface is located on the optical path of the laser beam of the laser directed onto the substrate and is located on the substrate.

3. The excimer laser annealing apparatus according to claim 2, wherein the reflective film comprises a first thin film layer and a second thin film layer alternately arranged in layers, and the first thin film layer is disposed on an outermost layer and an innermost layer of the reflective film, the first film layer has a first refractive index, the second film layer has a second refractive index, and the first refractive index is greater than the second refractive index.

4. The excimer laser annealing apparatus according to claim 3, wherein the first thin film layer and the second thin film layer have a same thickness.

5. The excimer laser annealing apparatus according to claim 4, wherein thicknesses of the first thin film layer and the second thin film layer are both an integral multiple of a quarter of a wavelength of the laser.

6. The excimer laser annealing apparatus according to claim 3, wherein the first thin film layer comprises at least one of a silicon nitride film layer, a titanium dioxide film layer, a tantalum pentoxide thin film layer, a zirconium oxide thin film layer, a lanthanum titanate thin film layer, a hafnium oxide thin film layer, and a zinc selenide thin film layer.

7. The excimer laser annealing apparatus according to claim 5, wherein the first thin film layer comprises at least one of a silicon nitride film layer, a titanium dioxide film layer, a tantalum pentoxide thin film layer, a zirconium oxide thin film layer, a lanthanum titanate thin film layer, a hafnium oxide thin film layer, and a zinc selenide thin film layer.

8. The excimer laser annealing apparatus according to claim 3, wherein the second thin film layer comprises at least one of a magnesium fluoride thin film layer, a silicon oxide thin film layer, an aluminum oxide thin film layer, and a titanium nitride thin film layer.

9. The excimer laser annealing apparatus according to claim 5, wherein the second thin film layer comprises at least one of a magnesium fluoride thin film layer, a silicon oxide thin film layer, an aluminum oxide thin film layer, and a titanium nitride thin film layer.

10. The excimer laser annealing apparatus according to claim 7, wherein the excimer laser annealing apparatus comprises an energy meter for detecting the energy of the laser reflected by the reflection film.

11. The excimer laser annealing apparatus according to claim 8, wherein the excimer laser annealing apparatus comprises a supporter that supports the substrate.

12. The excimer laser annealing apparatus according to claim 10, wherein the substrate is an amorphous silicon substrate.
